(19) United States
(12) Patent Application Publication
(10) Pub. No.: US 2006/0149691 A1
(43) Pub. Date: Jul. 6, 2006

(54) Method and system for enablement and management of ad hoc electric energy consumption

(75) Inventor: Eugene Sindambiwe, Mannheim (DE)

Correspondence Address: FOLEY & LARDNER LLP, 777 EAST WISCONSIN AVENUE, SUITE 3800, MILWAUKEE, WI, 53202-5308, US

(73) Assignee: SAP Aktiengesellschaft

(21) Appl. No.: 11/028,491

(22) Filed: Jan. 3, 2005

(51) Int. Cl. G01R 21/133

(52) U.S. Cl. 705/412

(57) ABSTRACT

An apparatus and method for providing electric energy in an ad hoc manner to a customer having an electrically-powered device, includes an electric connection unit configured to electrically connect to the electrically-powered device, the electric connection unit being in a default state in which electrical energy is not output from the electric connection unit. An input unit is configured to receive input, by the customer, of a mode of payment. A control unit is configured to control operation of the apparatus. An output unit is configured to provide a payment record to the customer when the customer has finished using the apparatus. The control unit controls operation of the electric connection unit to thereby allow electric energy to flow from the electric connection unit to the electrically-powered device coupled thereto, when the control unit has determined that the mode of payment provided to the input unit is acceptable.

### FIELD OF THE INVENTION

The present invention relates generally to the field of energy management, and in particular it relates to providing energy to users in an ad hoc manner, so that those users can utilize energy wherever they may be, and be billed for it in a convenient manner.

### BACKGROUND OF THE INVENTION

One of the most fundamental problems with devices that need electric energy to work is the accessibility of electric energy for mobile users. Mobile users of a notebook computer, a handheld computer, a mobile phone or similar devices often face this problem because wireless transportation of electric energy at large is not yet possible.

Though it is inconvenient, it seems unavoidable to take a battery pack along ones travels. But, again, this is not satisfactory because of insufficient storage capacity of batteries in general. The only one alternative is that these users find a place where they have ordered a service beforehand, which implicitly includes consumption of electric energy; e.g., a hotel room, a meeting room, etc. However, there are a lot of situations in which potential consumers of electric energy do not have such contract, such as when they are waiting at a public place. In this case, the problem is not a missing infrastructure to get connected to the electric supply network at that public location, rather it is the absence of a customer-supplier relationship and the fact that such a relationship cannot be established in an ad hoc fashion just to consume electric cannot be established in an ad hoc fashion just to consume electric energy for a short period, such as for twenty minutes for an energy consumption cost of just a few cents.

Even if this seems to be a small problem for one individual, it is a big problem on the worldwide scale. For example, one needs only to remember back to the significance of telephone booths before the advent of mobile phones. Finally, there are situations in which just changing the consumption place would not work, if the fallback of using a storage battery is not possible either, such as being in an electric car that just lost its power on a super-highway.

In view of the foregoing, it would be beneficial to provide a method and system that provides for the availability of electrical energy to consumers at a variety of locations, so that those consumers can utilize the electrical energy provided by an energy supplier in an ad hoc manner.

### SUMMARY OF THE INVENTION

The present invention relates to providing electrical energy services in an ad hoc manner to consumers.

According to a first aspect of an exemplary embodiment, there is a method of providing electric energy to a customer having an electrically-powered device. The method includes connecting, by the customer, the electrically-powered device to an electrical outlet of an apparatus, the electrical outlet being in a default state in which electrical energy is not output from the electrical outlet. The method also includes inputting, by the customer, a mode of payment to the apparatus. The method further includes providing, by the apparatus, electrical energy to the electrically-powered device coupled to the electrical outlet, by switching the electrical outlet so that it provides electrical energy to a device coupled thereto. The method still further includes providing a payment record to the customer when the customer has finished use of the apparatus.

According to another aspect of an exemplary embodiment, there is an apparatus for providing electric energy in an ad hoc manner to a customer having an electrically-powered device. The apparatus includes an electric connection unit configured to electrically connect to the electrically-powered device, the electric connection unit being in a default state in which electrical energy is not output from the electric connection unit. The apparatus also includes an input unit configured to receive input, by the customer, of a mode of payment. The apparatus further includes a control unit configured to control operation of the apparatus. The apparatus still further includes an output unit configured to provide a payment record to the customer when the customer has finished using the apparatus. The control unit controls operation of the electric connection unit to thereby allow electric energy to flow from the electric connection unit to the electrically-powered device coupled thereto, when the control unit has determined that the mode of payment provided to the input unit is acceptable.

According to yet another aspect of the invention, there is a system for providing electric energy in an ad hoc manner to a customer having an electrically-powered device. The system includes an apparatus that includes: a) an electric connection unit configured to electrically connect to the electrically-powered device, the electric connection unit being in a default state in which electrical energy is not output from the electric connection unit; b) an input unit configured to receive input, by the customer, of a mode of payment; c) a control unit configured to control operation of the apparatus; and d) an output unit configured to provide a payment record to the customer when the customer has finished using the apparatus, wherein the control unit controls operation of the electric connection unit to thereby allow electric energy to flow from the electric connection unit to the electrically-powered device coupled thereto, when the control unit has determined that the mode of payment provided to the input unit is acceptable. The system also includes at least one external system that is communicatively connected to the apparatus, and that performs a billing process for determining an amount of money to be billed the user, and that bills the user accordingly.

These and other benefits and features of embodiments of the invention will be apparent upon consideration of the following detailed description of preferred embodiments thereof, presented in connection with the following drawings in which like reference numerals are used to identify like elements throughout.

### BRIEF DESCRIPTION OF THE DRAWINGS

FIG. 1 is a block diagram of an energy supply system according to a first embodiment of the invention;

FIG. 2 is a state diagram showing the various states of an energy supply system according to the first embodiment of the invention.

FIG. 3 shows an energy supply system according to a second embodiment of the invention, which provides integration to local or remote billing systems.

FIG. 4 shows an energy supply system according to a third embodiment of the invention, which provides a grid services solution.

Before explaining several preferred embodiments of the present invention in detail it is noted that the invention is not limited to the details of construction or the arrangement of components set forth below or illustrated in the drawings. The particulars shown herein are by way of example and for purposes of illustrative discussion of the preferred embodiments only and are presented in a manner that is believed to provide the most useful and readily understood description of the principles and concepts of the present invention. In this regard, no attempt is made to show structural details of the present invention in more detail than is necessary to provide a fundamental understanding of the present invention. The description of the invention taken with the drawings is believed sufficient to make it apparent to those skilled in the art how several forms of the present invention may be embodied in practice. The invention is capable of other embodiments and being practiced or carried out in various ways. It is also noted that the phraseology and terminology employed herein is for purposes of description only and should not be regarded as limiting.

### DETAILED DESCRIPTION OF THE PREFERRED EMBODIMENTS

The present invention according to the several embodiments described herein provides for an increase in the overall accessibility of electrical energy to potential users. According to a first embodiment of the invention, an apparatus and software system removes current inhibitors to mobile ad hoc consumers from obtaining electrical energy. Since wireless transport of electric energy is not yet possible, the present invention according to the first embodiment enables an electric energy supply to a user upon an ad hoc contract between the user and a local energy supplier, as well as the handling of the business transaction also in an ad hoc fashion.

An apparatus and accompanying software according to the first embodiment can be packaged in one robust box and installed virtually anywhere; e.g., public places, gas stations, airport terminals, transportation vehicles, households, waiting and visitor rooms, classical telephone booths (which can readily be converted to electric energy boxes), etc. Note that no contractual relationship is assumed to be defined beforehand between the local electric energy supplier and potential consumers. In fact, it may not be feasible to maintain those relationships to all electric power suppliers and to all places. In addition, it is virtually impossible to maintain these relationships to a degree close to a person's mobility degree in today's world (e.g., with constant business trips, vacations, etc.). Finally, the present invention according to the first embodiment provides electric energy to a user practically instantaneously, which means that the contractual relationship and the following electric energy supply to the user are established in an ad hoc fashion and upon an ad hoc demand.

Still further, the present invention according to the first embodiment provides a system and method that manages billing and invoicing. The present invention according to the second embodiment integrates with one or more billing systems, which those billing systems may be local or remote, and whereby the connectivity to those billing systems may be via a Web-based application. The present invention according to the third embodiment integrates to a large scale, distributed and massively parallel system for management of ad hoc energy consumption relationships on the basis of Grid Services technology.

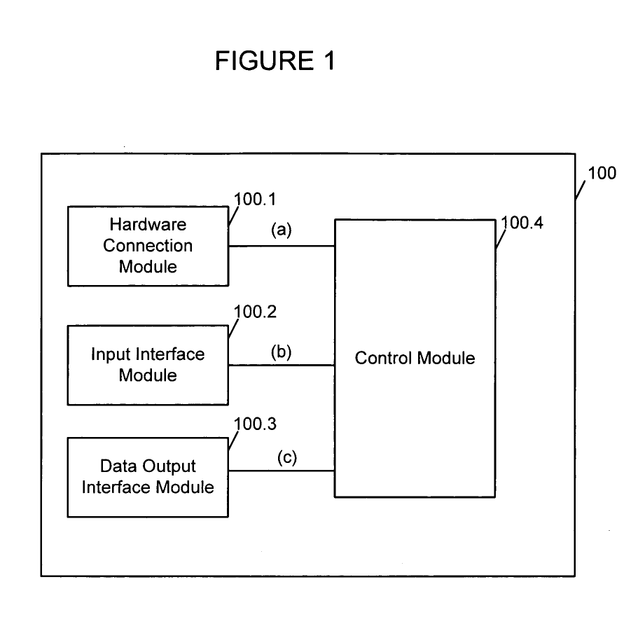

FIG. 1 shows an ad hoc energy supply apparatus 100 in block diagram form, according to a first embodiment of the invention. Each of the blocks shown in FIG. 1 includes software programmed to perform particular tasks to be described in detail below. The apparatus 100 comprises four components or modules: 100.1, 100.2, 100.3 and 100.4 The function of each of these modules is described in detail below.

Module 100.1 is a hardware connection interface module. Module 100.1 is the technical access point for electrical energy, and it includes one or more power sockets that comply with different standards; e.g., European standard or U.S. standard. That way, electrical energy can be provided to different types of devices that come from different parts of the world and are made by different vendors. However, unlike standard electrical energy sockets, the power socket(s) of module 100.1 are disabled in their default mode of operation. Thus, users of the apparatus 100 plug in an electric powered device (e.g., a notebook computer, or simply a battery charger), which is assumed to be electric powered, into an appropriate socket offered by module 100.1, but (unlike standard power sockets) flow of electric energy does not immediately take place if the electric power device is switched on.

Module 100.2 is an input interface module. Module 100.2 is an input device for digital data, whereby it may include one or more different types of input devices for receiving physical objects that may be required; e.g., coins, bank notes, smart cards with electrically readable chips. Module 100.2 may include a plurality of slots and corresponding readers for reading specific devices that can be inserted into the slots. Module 100.2 may also includes one or more switches, a touch screen, a computer mouse, a graphical display to allow a user to select among preconfigured menu items, a reader of a card with pre-saved data on it (e.g., a bank or credit card reader, and/or a card with a chip that allows for a certain amount of usage of electrical energy), and a keyboard. All of these inputs allow a user to select an amount of electrical energy usage to pay for, and the mode of payment. Typically, not all of these alternatives may be utilized in one apparatus 100, but there likely will exist a subset of these alternatives, depending upon the location of the apparatus 100 (e.g., at an airport, at a gas station), the specific type of apparatus 100 that a franchisee is willing to pay for (whereby the franchisee obtains a percentage amount of the total sales made from the apparatus 100), as well as other parameters.

Besides the requirement to plug in an electric power device into the hardware connection module 100.1, a user of the apparatus 100 needs to enter in data using one of the options described above, so as to activate the hardware connection module 100.1 (so that electric energy can then flow into the user's device connected to the module 100.1). For example, if the user enters in $5.00 in bank notes or coins into coin-accepting slots and bank-note-accepting slots of the module 100.2, then the apparatus 100 then allows for electric energy to flow through the module 100.1 and thereby into the user's device connected to the module 100.1.

Module 100.3 is a data output interface module. Module 100.3 may include diode lamps, a screen (e.g., a touch screen), slots (for use as input and output channels for cards), a graphical display, and a paper printer. Module 100.3 may also provide capabilities to send the output as an e-mail or as a facsimile to an appropriate location (or in-box). Some of the features of module 100.3 may be user-selectable; e.g., sending some output to an e-mail address, whereas other features may not be user-selectable, depending upon the particular type of apparatus 100 to be used for a particular location. Module 100.3 may also include a screen that provides a visual indication of the current internal operating state of the apparatus 100.

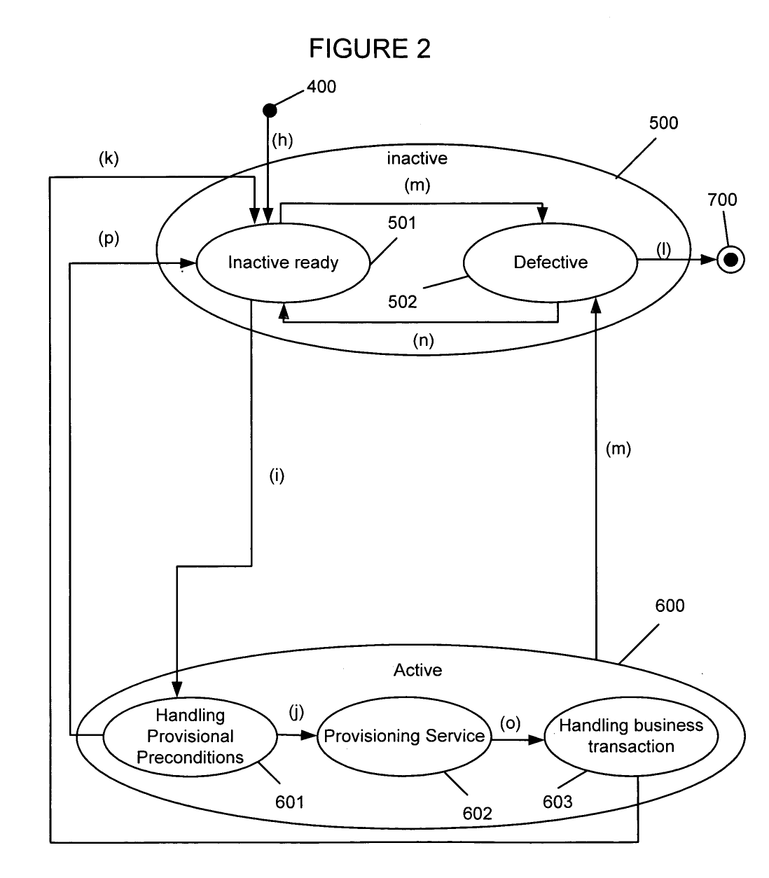

Module 100.4 is a control module for the apparatus 100, whereby it controls all of the other modules 100.1, 100.2 and 100.3 of the apparatus 100. Module 100.4 implements the state machine shown in FIG. 2. In detail, FIG. 2 is a state diagram with an initial state 400 and a final state 700. According to standard state diagram terminology, initial and final states are referred to as pseudo states, because the apparatus 100 cannot really be in either of these states. The initial state 400 corresponds to a time period before the apparatus 100 has started to exist or to be considered. The final state 700 corresponds to a time period from the instant when the apparatus 100 runs out of use or is no longer of interest.

The first state that the apparatus 100 can be in is state 501, which is the inactive-ready state, whereby the apparatus 100 transitions to the inactive-ready state 501 from the initial state 500 by way of transition event (h). As stated above, transition (h) automatically occurs once the apparatus 100 is configured to use, whereby transition (h) does not require any external event. Inactive-ready state 501 is the state that the apparatus 100 is in once it is properly installed at a particular location. When in state 501, the apparatus 100 is ready to be used, but the apparatus 100 as a whole, and module 100.4 in particular, does not perform any action at this time. Therefore, the state 501 is call “inactive ready.”

Upon external event (i), which is when an input item is entered over input interface 100.2, or an electric power device is plugged in over module 100.1, the apparatus 100 enters the ‘handling provisioning preconditions’ state 601. When in state 601, the apparatus 100 starts receiving and checking input data from module 100.2, and may include checking whether the device coupled to an electrical outlet of module 100.1 fits properly within that electrical outlet. The apparatus 100 remains in state 601 until all preconditions for provisioning electric energy are fulfilled or when either one of events (j), (m) or (p) is triggered.

In the absence of irregularities (e.g., fake coins entered into a slot of module 100.2), event (j) is triggered next. Event (j) corresponds to the user having plugged in a serviceable electric powered device into interface 100.1, and having entered valid required input data (e.g., a proper password of the user that is entered by way of a touch screen of module 100.2) and/or physical objects over input module 100.2 that finally requests provision of electric energy. The user may do this implicitly, e.g., by having entered the last required input item, or explicitly, e.g., by confirming completion of input data entry over a dedicated input interface item, such as by clicking on a confirmation button on a touch screen of input module 100.2.

On event (j), the apparatus 100 enters state 601. Module 100.4, among others, switches on supply of electric energy, whereby electricity flows to and from devices connected over sockets of module 100.1, provided that those devices are turned on. Module 100.4 includes a meter to provide the user with a running total of the electrical energy consumed up to a particular moment in time. The counted values may be part of the output to module 100.3 that are sent periodically (e.g., near real time). Besides or instead of providing evidence of the amount of provisioned electric energy, the module 100.4 may display costs so far caused by the consumed amount. This amount may refer to a particular currency, which depends on a customer parameter or the location of the apparatus 100, and it may be provided periodically or at the end of the energy provisioning. In a different implementation, only the final consumption amount is provided to the user upon the user's indication to end the consumption of electric energy to one or more devices of the user that are connected to module 100.1. The electric meter may be a part of module 100.4, or external to it, whereby FIG. 1 does not distinguish between these two cases explicitly. In either case, the electric meter is reset instantaneously and restarted on event (j).

When the apparatus 100 is in either one of the sub-states 601, 602 and 603, i.e., in the conceptual compound state 600, the user is not able to retrieve any physical objects inserted into the apparatus 100 via interface 100.2 (e.g., inserted coins and/or bank notes, a prepaid smart card, a credit card, etc.) that are required in order to prevent the user from leaving the consumption site (where the apparatus 100 is located) prior to the apparatus entering and completing the ‘handling business transaction’ state 603.

The apparatus 600 performs transition from the ‘provisioning service’ state 602 to state 603 on event (o). Event (o) has different variants, such as the user explicitly requesting to complete the technical transaction (end of electric energy consumption) which thereby causes the system to start the ‘wrap up’ business transaction to thereby compute a bill for the user. Event (o) also may correspond to an event in which the apparatus 100 has detected the removal of all electric devices that had been previously plugged into electrical outlets of module 100.1, and, after a timeout interval (e.g., 1 to 2 minutes), request user confirmation to wrap up the transaction. This may also provide some help to the user to remind the user to not leave the consumption site in a state where the apparatus 100 may still hold onto one or more physical objects of the user, e.g., the user's credit card. Event (o) may also be internally triggered by module 100.4, after having detected a situation in which the supply of electric energy does no longer make sense from a business perspective. This may occur, for example, when the consumption costs nearly reach the total available amount available (e.g., pre-paid amount) or a maximum value that may be determined by the electric energy supplier (e.g., maximum value per day, maximum value depending on customer properties, maximum value depending upon mode of payment, etc.).

Once event (o) is triggered, the apparatus 100 enters state 603, in which wrap up of the technical transaction and the execution of the business transaction takes place. Wrapping up the technical transaction, among other things, means that the flow of electric energy to devices that may still be connected to module 100.1 is interrupted. Moreover, the total number of units of electric energy consumption is determined, such as from a current reading of the meter.

Module 100.4 also preferably includes some billing logic, which determines consumption costs depending upon the total consumption amount and tariff conditions. Like the maximum values, tariff conditions may be specific to the electric energy supplier, the consumption time (e.g., during a peak period of the day, whereby the consumption rates are higher than during other times), or involve consumer properties that are identifiable through entered data and/or physical objects. For example, users who are employees of a certain company, e.g., SAP AG, may be provided with a predetermined discount for use of electric energy.

Apparatus 100, when used as a standalone solution, such as in the first embodiment, contains the invoicing logic discussed above, whereas in solutions such as described below with respect to second and third embodiments, part or all of the invoicing logic may be externally hosted. Moreover, the output of the invoicing logic may be converted to a suitable version that is sent to module 100.3 to provide ‘e vidence’ (e.g., a receipt) of the business transaction to the end user. In turn, this output may be displayed electronically, and/or a paper receipt printed out and/or sent to an e-mail address and/or a facsimile address. Therefore, module 100.4 is adapted to the particular implementation of apparatus 100, and to the particular choice made to implement module 100.3.

In particular, the business transaction enforces payment to the invoice. It may retain the invoice amount from the total amount available of a prepaid card provided by the user to the apparatus, for example (in cash or in virtual money), or save the billable amount together with other transaction data onto a non-volatile storage device (e.g., Compact Disc) that may be removed later on from the apparatus 100 and manually transported to another place to thereby import invoicing data to an external billing system, or that can be remotely accessed by an appropriate program.

State 502 corresponds to an ‘irregular’ state, in the sense that it is only entered when the apparatus 100 is technically defective, or when the apparatus 100 cannot be used because of errors that cannot be handled by module 100.4. Event (m) may result from acts of vandalism to the apparatus 100, from a technical wastage, from an internal overflow of any buffer (e.g., memory full) within module 100.4, etc. Apparatus 100 may be recoverable, i.e., transition from state 502 to state 501 via transition (m), through mechanical repair by a maintenance engineer or application of a software patch to apparatus 100.

When event (m) is triggered when the apparatus 100 is in state 601, 602 or 603, it may not be possible to wrap up the technical transaction and/or the business transaction properly. In that case, event (n) causes the apparatus 100 to be re-initialized technically and business-wise semantically. Thereby, it cannot be avoided, at least in some seldom cases, that some consumption of electric energy cannot be invoiced and billed to the consumer.

If the apparatus 100 is in either one of the sub-states 501, 502 of the compound state inactive 500, any physical objects required to correctly close the business transaction (e.g., a credit card) and that were provided to the apparatus 100 by the consumer cannot be removed from the apparatus 100. This corresponds to event (I), which leads to the final state 700. When the apparatus is in state 601, the user may be enabled to swap the system back to state 501, such as by triggering a reset event (p), because in that instance neither the technical transaction nor the business transaction has started. There is preferably provided a ‘reset’ button at a prominent location on the apparatus 100.

When the apparatus 100 is in the ‘handling business transaction’ state 603, the end of the business transaction automatically triggers event (k), to thereby return the apparatus to inactive-ready state 501.

In the first embodiment, when the reset button is pushed on the apparatus 100 while the apparatus 100 is in state 602, the technical transaction and the business transaction are wrapped up, and the apparatus automatically goes to inactive-ready state 501, whereby the user can then get back any physical objects (e.g., credit cards, remaining amount of value from cash or coins entered into the apparatus 100 by way of module 100.2) from the apparatus 100.

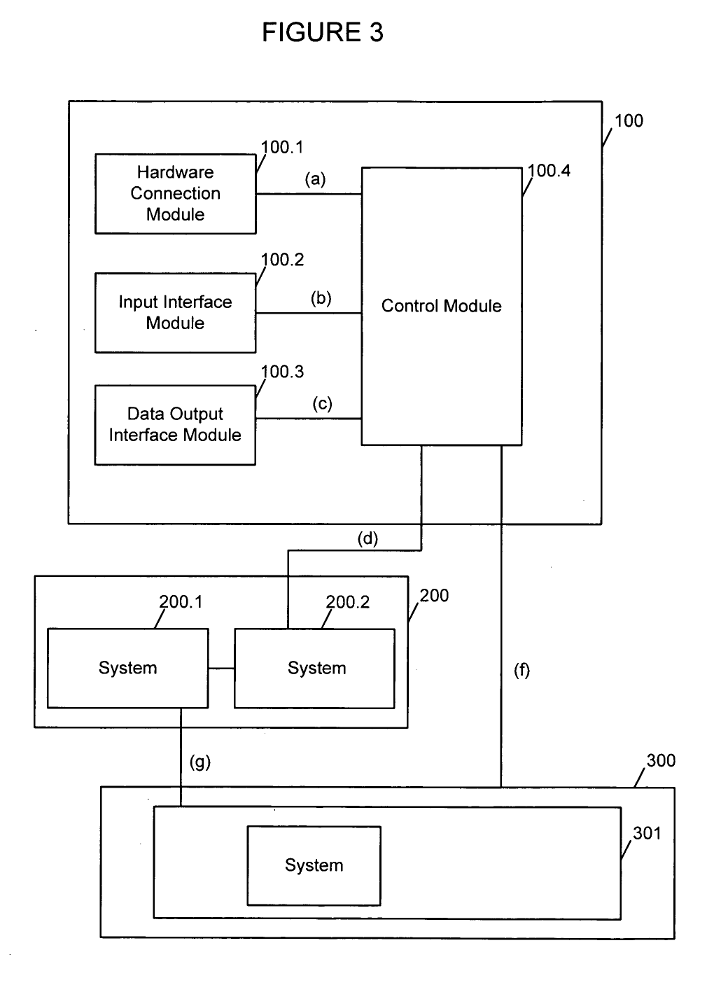

FIG. 3 is a block diagram of a system according to a second embodiment, which provides for integration of an ad hoc energy supply apparatus 100 to external systems 200 and 300. The second embodiment may be implemented with system 200 without system 300, or system 300 without system 200, or with both systems 200 and 300 together. For instance, system 200 may be used without system 300, in a case where system 200 corresponds to a billing system of a local energy supplier (that supplies the electric energy to the apparatus 100, to then be sold to consumers in an ad hoc fashion). Based on the actual location of the apparatuses 100.1, 100.2, 100.3, one of the local electric energy suppliers 200.1, 200.2 would be assigned to provide electric energy for each of those apparatuses. In a preferred implementation of the second embodiment, the consumer identity, contractual tariff, payment conditions, etc., may be available in the billing system 200. The billing system 200 may be able to aggregate the invoice amounts for ad hoc consumptions of electric energy at different places, but in the same area, to the regular invoice of home-based energy consumptions, and thereby issue a single bill to the consumer (e.g., on a monthly basis).

The integration may also be possible without mobility considerations, e.g., to enable pre-paid, but ad hoc services to supply electric energy, for example, to payers with bad credit. If system 200 is utilized for providing billing as in the second embodiment, module 100.4 may be utilized to just collect the total consumption amount, and then to provide that information to the system 200. In that case, referring now to FIG. 2, a state machine with state 603 reduced to just performing a connection to system 200 would be utilized by the apparatus 100 in the second embodiment.

The business transaction is preferably implemented and executed on system 200, in the second embodiment. In a different implementation of the second embodiment, there are duplicate data maintained on system 200 and system 300, e.g., customer data and consumption amounts for tracking purposes, even if it is system 300 alone that performs the billing (alone or together with the invoicing), whereby this may be done synchronously or asynchronously.

In the second embodiment, system 300 may be used without system 200, whereby system 200 would be a system that is aware of the identify of the local electric energy supply. Moreover, system 300 is preferably hosted by a legal entity that acts on the behalf of the local energy supplier, to bill the consumption. The local energy supplier may be transparent to the electric energy consumer even on bills that the consumer may receive from his/her local energy supplier at a later date. Therefore, system 300 may be used without system 200, by way of a mechanism that ensures that the local electric energy supplier actually receives the money that the consumer owes him (by way of usage of electric energy via the apparatus 100).

An example of the usage of systems 200 and 300 in conjunction with each other is the integration of a billing system from the local energy supplier and a billing system from a home electric company (to the consumer). In the case, system 200 may be sent energy consumption data from the apparatus 100 over channel (d), whereas system 300 may receive other data sent from the apparatus 100 over channel (f). System 300 may also receive data from system 200 over channel (g), to allow system 300 to perform its part of the business transaction. For instance, system 300 may enable transparency of system 200 to the end user, but at the same time the local energy supplier would track the money the remote energy supplier is responsible to bill on its behalf.

In another implementation of the second embodiment, system 300 may be any billing system, e.g., an entity that offers billing services even without being an electric utility company. Additionally, the apparatus 100, the system 200 and the system 300 may be at three different geographic locations. They are preferably connected to each other over a local area network (LAN), a wide area network (WAN), or the Internet. The communication channels (d), (f) and (g) may be realized using standard communication protocols, such as HTTP, HTTPS, TCP/IP, or more complex ones, as Web services standards.

As explained above, system 300 may be a billing system that does not know the identity of the user of the apparatus 100, but whereby it can connect to the user's local energy supplier (system 200) to thereby get the user information needed to bill the user. In that instance, the system 200 may be the actual one that bills the user, such as on a monthly basis, whereby the user's bill will include energy usage fees for using the apparatus 100 during that last month, as well as fees for energy usage at the user's home.

In a different implementation, system 200 may correspond to an entity that owns the physical infrastructure, such as the network owner, and system 300 may be the energy supplier or energy dealer. Whoever sends the final bill to the user would then include fees for all portions of the system that are used to provide electric energy to the user of the apparatus 100, whereby the collected fees from the user would then be divided up and sent to each of the entities involved in providing the electric energy to the user.

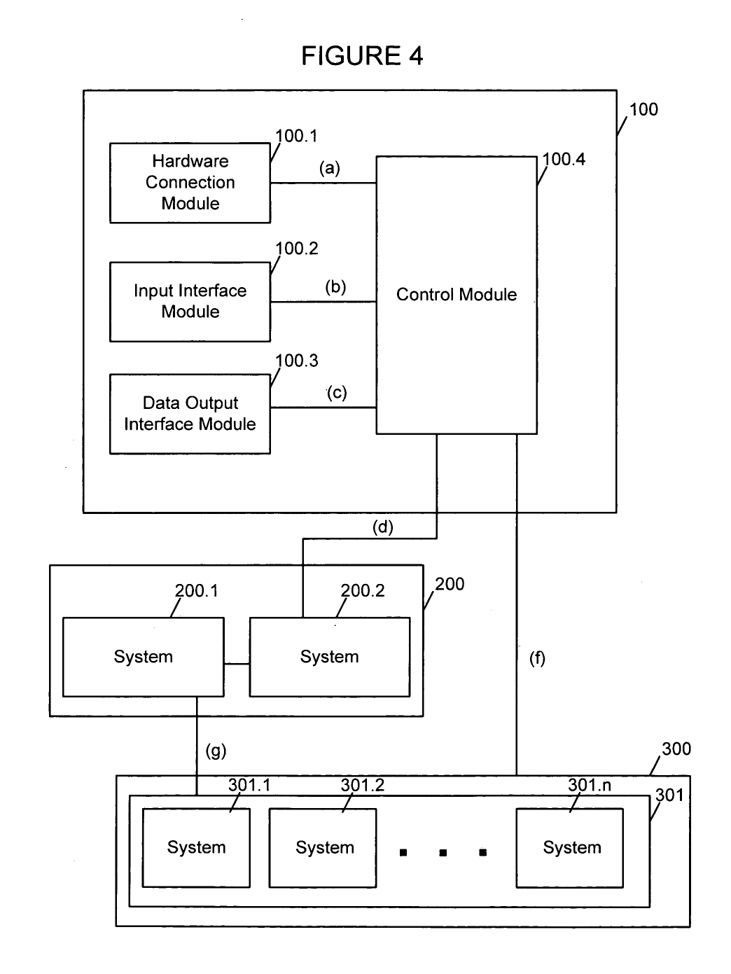

FIG. 4 is a block diagram that corresponds to a massively parallel business application, in accordance with a third embodiment of the invention. Because the third embodiment provides a decentralized solution to electric energy provisioning, and because there are no dependencies between solution subsets provided at any pair of places, the solution is, by nature, computationally intensive and parallelizable. Therefore, in the third embodiment, a solution that is based on the Grid Services architecture is utilized, whereby apparatuses 100.1, 100.2, 100.3, connect to energy suppliers 200.1, 200.2, and whereby system 300 corresponds to sub-systems 300.1, 300.1, . . . , 300.n.

In one possible implementation of the third embodiment, there are provided millions of different apparatuses 100 located throughout the World, and whereby there would be provided thousands of systems 200 (e.g., 200.1, 200.2, . . . ), which would be directly or indirectly connected to a massively parallel grid. The grid itself corresponds to a large scale business application that may be run by a non-electric utility company, or by any type of entity for that matter. In the third embodiment, electric utilities would assume the customer roles towards legal owner of the grid application.

As one example, assume that a user goes on a trip to different countries, whereby that user utilizes different apparatuses 100.1, 100.2 and 100.3 along his/her travels. Each system 200.1, 200.2 that provides electrical energy to the respective apparatuses 100.1, 100.2, 100.3 determines an amount of usage by the user at those apparatuses, whereby this information is provided to the billing system 300 via channel (g). The billing system 300 then collects that information provided to it by system 200, and determines a single bill to be sent to the user.

In one possible implementation of the third embodiment, sub-system 300.1 is used to compute bills for apparatuses 100 in one geographical area (e.g., the United States or a region thereof), sub-system 300.2 is used to compute bills for apparatuses 100 in another geographical area (e.g., Europe or a region thereof), and so on. Once system 300 has finished determining the final bill for a consumer, it sends its results to the local energy supplier of the consumer, whereby that local energy supplier may correspond to sub-system 200.2, and whereby the consumer is then billed for the amount of energy used at the apparatuses 100.

Alternatively, system 300 computes both the monetary usage of a consumer (by way of information provided to it from the apparatus over line (f)) and the bill, and whereby the user is then billed directly at the apparatus 100 (again, via information provided to the apparatus 100 from the system 300 over line (f)).

In yet another alternative implementation of the third embodiment, the energy transaction is between apparatus 100 and system 200 while the user is obtaining energy from the apparatus, and, once the transaction is completed, system 200 connects to system 300, which performs follow-up processing (e.g., to actually effect transfer of funds from an account of the user to the energy supplier that supplied the electric energy to the user).

It is envisioned that, in at least one embodiment of the invention, the electrical energy rates for energy usage at an apparatus 100 are marked up from what they would be if that same amount of energy was used at a user's home, whereby the mark-up would be justified based on the ‘convenience of service’ provided by way of the apparatus 100.

As noted above, embodiments within the scope of the present invention include program products comprising computer-readable media for carrying or having computer-executable instructions or data structures stored thereon. Such computer-readable media can be any available media that can be accessed by a general purpose or special purpose computer. By way of example, such computer-readable media can comprise RAM, ROM, EPROM, EEPROM, CD-ROM or other optical disk storage, magnetic disk storage or other magnetic storage devices, or any other medium which can be used to carry or store desired program code in the form of computer-executable instructions or data structures and which can be accessed by a general purpose or special purpose computer. When information is transferred or provided over a network or another communications connection (either hardwired, wireless, or a combination of hardwired or wireless) to a computer, the computer properly views the connection as a computer-readable medium. Thus, any such connection is properly termed a computer-readable medium. Combinations of the above are also to be included within the scope of computer-readable media. Computer-executable instructions comprise, for example, instructions and data which cause a general purpose computer, special purpose computer, or special purpose processing device to perform a certain function or group of functions.

The invention is described in the general context of method steps, which may be implemented in one embodiment by a program product including computer-executable instructions, such as program code, executed by computers in networked environments. Generally, program modules include routines, programs, objects, components, data structures, etc. that perform particular tasks or implement particular abstract data types. Computer-executable instructions, associated data structures, and program modules represent examples of program code for executing steps of the methods disclosed herein. The particular sequence of such executable instructions or associated data structures represents examples of corresponding acts for implementing the functions described in such steps.

In some embodiments, the present invention may be operated at a networked environment using logical connections to one or more remote computers having processors. Logical connections may include a local area network (LAN) and a wide area network (WAN). These are presented here by way of example, not limitation. Such networking environments are commonplace in office-wide or enterprise-wide computer networks, intranets and the Internet. Those skilled in the art will appreciate that such network computing environments will typically encompass many types of computer system configurations, including personal computers, hand-held devices, multi-processor systems, microprocessor-based or programmable consumer electronics, network PCs, minicomputers, mainframe computers, and the like. The invention may also be practiced in distributed computing environments where tasks are performed by local and remote processing devices that are linked (either by hardwired links, wireless links, or by a combination of hardwired or wireless links) through a communications network. In a distributed computing environment, program modules may be located in both local and remote memory storage devices.

An exemplary system for implementing the overall system or portions of the invention might include a general purpose computing device in the form of a conventional computer, including a processing unit, a system memory, and a system bus that couples various system components including the system memory to the processing unit. The system memory may include read only memory (ROM) and random access memory (RAM). The computer may also include a magnetic hard disk drive for reading from and writing to a magnetic hard disk, a magnetic disk drive for reading from or writing to a removable magnetic disk, and an optical disk drive for reading from or writing to removable optical disk such as a CD-ROM or other optical media. The drives and their associated computer-readable media provide nonvolatile storage of computer-executable instructions, data structures, program modules and other data for the computer.

Software and Web-based implementations of the present invention could be accomplished with standard programming techniques with rule based logic and other logic to accomplish the various database searching steps, correlation steps, comparison steps and decision steps. It should also be noted that the word “component” as used herein and in the claims is intended to encompass implementations using one or more lines of software code, and/or hardware implementations, and/or equipment for receiving manual inputs.

The foregoing description of embodiments of the invention has been presented for purposes of illustration and description. It is not intended to be exhaustive or to limit the invention to the precise form disclosed, and modifications and variations are possible in light of the above teachings or may be acquired from practice of the invention. The embodiments were chosen and described in order to explain the principals of the invention and its practical application to enable one skilled in the art to utilize the invention in various embodiments and with various modifications as are suited to the particular use contemplated. In one possible implementation, conventional telephone booths, which have become practically useless in today's world due to the use of cellular phones, can be retrofitted to thereby be used as locations for ad hoc energy supply apparatuses described hereinabove.

What is claimed is:

1. A method of providing electric energy to a customer having an electrically-powered device, comprising:
a) connecting, by the customer, the electrically-powered device to an electrical outlet of an apparatus, the electrical outlet being in a default state in which electrical energy is not output from the electrical outlet;
b) inputting, by the customer, a mode of payment to the apparatus;
c) providing, by the apparatus, electrical energy to the electrically-powered device coupled to the electrical outlet, by switching the electrical outlet so that it provides electrical energy to a device coupled thereto; and
d) providing a payment record to the customer when the customer has finished use of the apparatus.

2. The method of claim 1, wherein the mode of payment includes: i) inputting currency or coins through a slot of the apparatus, or ii) inputting a smart card that contains information for charging an account of the customer.

3. The method of claim 1, wherein the payment record is provided to the customer by way of a paper printout.

4. The method of claim 1, wherein the payment record is provided to the customer when either the mode of payment provided by the customer has run out of funds, or the customer has disconnected the electrically-powered device from the electrical outlet of the apparatus.

5. The method of claim 1, wherein the step d) comprises:
determining a mode of billing the customer;
determining an amount of electrical energy consumed by the electrically-powered device coupled to the electrical outlet; and
billing the customer for the amount of electrical energy consumed by the electrically-powered device.

6. The method of claim 1, further comprising:
detecting a reset condition initiated by the customer;
stopping the providing of electrical energy by way of the electrical outlet;
billing the customer for electrical energy used; and
returning to a default state of the apparatus.

7. The method of claim 1, further comprising:
connecting to a billing unit by way of a network connection, in order to perform the step d).

8. The method of claim 7, wherein the connecting step comprises:
connecting to one of a plurality of billing units.

9. The method of claim 4, wherein the step of determining an amount of electrical energy consumed by the electrically-powered device is performed by a first system separate from the apparatus, by way of a communicative connection between the apparatus and the first system.

10. The method of claim 9, wherein the step of billing the customer is performed by a second system separate from the first system and separate from the apparatus.

11. An apparatus for providing electric energy in an ad hoc manner to a customer having an electrically-powered device, comprising:
an electric connection unit configured to electrically connect to the electrically-powered device, the electric connection unit being in a default state in which electrical energy is not output from the electric connection unit;
an input unit configured to receive input, by the customer, of a mode of payment;
a control unit configured to control operation of the apparatus; and
an output unit configured to provide a payment record to the customer when the customer has finished using the apparatus,
wherein the control unit controls operation of the electric connection unit to thereby allow electric energy to flow from the electric connection unit to the electrically-powered device coupled thereto, when the control unit has determined that the mode of payment provided to the input unit is acceptable.

12. The apparatus according to claim 11, wherein the input unit includes a first unit for receiving currency and/or coins, and a second unit for receiving a credit card or other type of smart card.

13. The apparatus according to claim 11, wherein the electric connection unit includes a plurality of different types of electrical outlets.

14. The apparatus according to claim 11, further comprising:
a reset control,
wherein, upon activation of the reset control by the user, the apparatus stops providing of electrical energy to the electrically-powered device, and initiates computation of a billing amount to thereby bill the user for services rendered.

15. A system for providing electric energy in an ad hoc manner to a customer having an electrically-powered device, comprising:
an apparatus that includes:
an electric connection unit configured to electrically connect to the electrically-powered device, the electric connection unit being in a default state in which electrical energy is not output from the electric connection unit;
an input unit configured to receive input, by the customer, of a mode of payment;
a control unit configured to control operation of the apparatus; and
an output unit configured to provide a payment record to the customer when the customer has finished using the apparatus,
wherein the control unit controls operation of the electric connection unit to thereby allow electric energy to flow from the electric connection unit to the electrically-powered device coupled thereto, when the control unit has determined that the mode of payment provided to the input unit is acceptable; and
at least one external system that is communicatively connected to the apparatus, and that performs a billing process for determining an amount of money to be billed the user, and that bills the user accordingly.

16. The system according to claim 15, wherein the at least one external system comprises:
a first external system that determines the amount of money to be billed the user; and
a second external system that has stored therein particular information of the user to be used in sending a bill to the user.

17. The system according to claim 15, wherein the at least one external system comprises:
a first external system that includes a plurality of sub-systems; and
a second external system that includes a plurality of sub-systems,
wherein the first external system, the second external system and the apparatus are connected to each other by way of a connection grid.

18. The system according to claim 17, wherein the plurality of sub-systems of the first external system are respectively assigned to a plurality of apparatuses, based on locations of the plurality of apparatuses with respect to the plurality of sub-systems of the first external system.
